(19) United States
(12) Patent Application Publication
(10) Pub. No.: US 2025/0236948 A1
(43) Pub. Date: Jul. 24, 2025

(54) VAPOUR NOZZLE FOR PVD

(71) Applicant: ArcelorMittal, Luxembourg (LU)

(72) Inventors: Vincent RUWET, Visé (BE); Sergio PACE, Jodoigne (BE); Océane GILLET, Liège (BE)

(21) Appl. No.: 18/700,663

(22) PCT Filed: Sep. 5, 2022
(86) PCT No.: PCT/IB2022/058332

§ 371 Date: Apr. 11, 2024

(30) Foreign Application Priority Data
Oct. 14, 2021 (WO) PCT/IB2021/059432

(51) Int. Cl. C23C 14/56; C23C 14/16; C23C 14/24; C23C 14/58

(52) U.S. Cl. CPC C23C 14/562; C23C 14/16; C23C 14/243; C23C 14/58

(57) ABSTRACT

A vapour jet coater for depositing, on a running substrate, coatings formed from metal or metal alloy, the vapour jet coater including successively a repartition chamber, configured to be connectable to an evaporation pipe, and a vapour outlet orifice, connected to said repartition chamber and able to eject a metal alloy vapour along a main ejection plan and a main ejection direction, comprising successively i. a converging section, ii. a diverging section.

The present invention relates to a vapour jet coater and a vacuum deposition facility for continuously depositing metallic coatings. This invention also relates to a depositing method of such coatings.

The invention is particularly intended for depositing a zinc or zinc-magnesium based coatings onto a running steel strip without being limited thereto. Such coated steel strip can then be cut and shaped, for example by stamping, bending or shaping, to form a part that can then be painted.

### BACKGROUND

Several coating methods exist such as hot-dip coating and electrocoating. However, these conventional methods do not provide a satisfying coating for steel grades containing high level of oxidizable elements such as Si, Mn, Al, P, Cr or B. Consequently, new methods have been developed e.g. vacuum deposition technologies such as JVD (Jet Vapour Deposition).

In JVD, a metallic vapor spray, propelled at a supersonic speed, comes into contact with the substrate. WO97/47782 and WO2009/047333 describe such process.

WO 2015/015237 and discloses a process aiming to improve the temporary protection against corrosion of steel coated by JVD (Jet Vapour Deposition). This is done by coating the steel substrate in a vacuum deposition facility wherein a ratio between a pressure inside a deposition chamber and a pressure inside a zinc ejection chamber is between 2×10⁻³ and 5.5×10⁻².

WO 2019/239314 discloses a vapour jet coated preventing microdroplet-like defects. As illustrated in FIG. 1, this vapour jet coater 101 is formed of a repartition chamber 102 and a vapour outlet orifice 103 comprising a converging section 104.

### SUMMARY OF THE INVENTION

Nevertheless, it has been observed that the equipment of the prior art leads to a vacancy concentration of about 2%. This limits the mechanical resistance of the coating and causes coating adherence issues limiting the thickness of the coating.

An aim of the present invention is to remedy the drawbacks of the facilities and processes of the prior art.

The present invention provides a vapour jet coater 1 for depositing, on a running substrate (S), coatings formed from metal or metal alloy, said vapour jet coater comprising successively:
a repartition chamber 2, configured to be connectable to an evaporation pipe, and
a vapour outlet orifice 3, connected to said repartition chamber 2 and able to eject a metal alloy vapour along a main ejection plan (P) and a main ejection direction (D), comprising successively
i. a converging section 4 comprising a wall defining two converging faces (5, 6), one on each side of said ejection plan (P), wherein said two faces (5, 6) are spaced from a distance C_{ENTRY} on an entry side and from a distance C_{EXIT} on an exit side, wherein a ratio C_{EE} (C_{ENTRY}/C_{EXIT}) is from 1.2 to 10.
ii. a diverging section 7 comprising a wall defining two diverging faces (8, 9), one on each side of said ejection plan (P), wherein said two faces (8, 9) are spaced from a distance D_{ENTRY} on an entry side and from a distance D_{EXIT} on an exit side, wherein a ratio D_{EE} (D_{ENTRY}/D_{EXIT}) is from 0.1 to 0.8.

The present invention also provides a method for continuously depositing, on a running substrate (S), coatings formed from at least one metal inside a vacuum deposition facility according to claim 7, wherein the method comprises a step in which, in said vacuum chamber having a pressure P_{VACUUM}, a metallic vapour is ejected through at least one vapour outlet orifice, at a pressure P_{EJECTED}, towards a side of said running substrate and a layer of at least one metal is formed wherein (P_{EJECTED}/P_{VACUUM}) is from 2 to 15 and the ejected vapour has a supersonic speed at said entry side of said diverging section 7.

Other characteristics and advantages will become apparent from the following detailed description of the invention.

### BRIEF DESCRIPTION OF THE DRAWINGS

To illustrate the invention, various embodiment will be described, particularly with reference to the following figures:

FIG. 1 is an embodiment of a vapour jet coater according to the prior art.

FIG. 2 is an embodiment of a vapour jet coater according to the invention.

FIG. 3 is a first embodiment of a vapour outlet orifice according to the invention.

FIG. 4 is a second embodiment of a vapour outlet orifice according to the invention.

FIG. 5 is an embodiment of a vacuum deposition facility according to the invention.

FIG. 6 is a SEM image of a coating realised with a vapour jet coater according to the prior art.

FIG. 7 is a SEM image of a coating realised with a vapour jet coater according to the invention.

### DETAILED DESCRIPTION

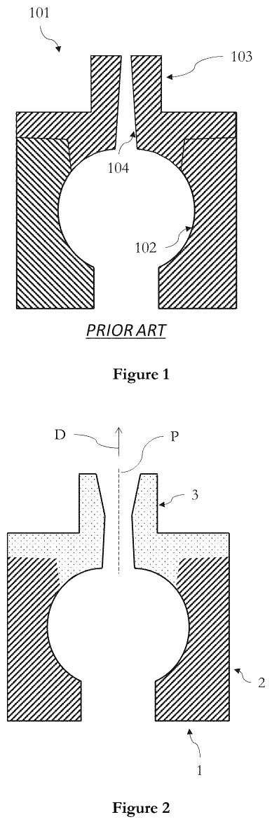

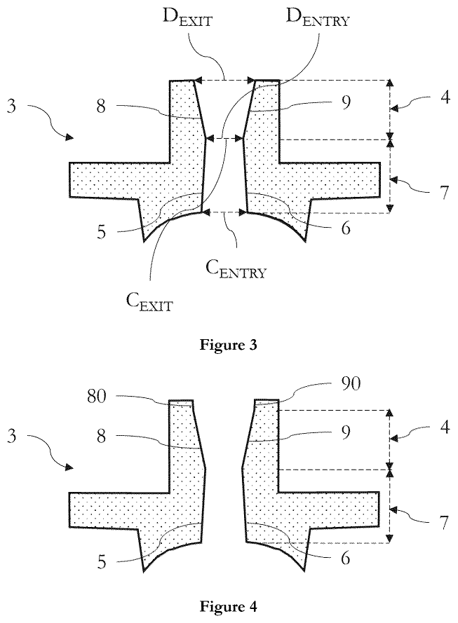

The invention, as illustrated in FIG. 2 and FIG. 3, relates to a vapour jet coater 1 for depositing, on a running substrate (S), coatings formed from metal or metal alloy, said vapour jet coater comprising successively:
a repartition chamber 2, configured to be connectable to an evaporation pipe, and
a vapour outlet orifice 3, connected to said repartition chamber 2 and able to eject a metal alloy vapour along a main ejection plan (i.e. plane) (P) and a main ejection direction (D), comprising successively:
   i. a converging section 4 comprising a wall defining two converging faces (5, 6), one on each side of said ejection plan (P), wherein said two faces (5, 6) are spaced from a distance C_{ENTRY} on an entry side and from a distance C_{EXIT} on an exit side, wherein a ratio C_{EE} (C_{ENTRY}/C_{EXIT}) is from 1.2 to 10.
   ii. a diverging section 7 comprising a wall defining two diverging faces (8, 9), one on each side of said ejection plan (P), wherein said two faces (8, 9) are spaced from a distance D_{ENTRY} on an entry side and from a distance D_{EXIT} on an exit side, wherein a ratio D_{EE} (D_{ENTRY}/D_{EXIT}) is from 0.1 to 0.8.

In the following, the main ejection direction (D) is expressed relative to the movement of the ejected metal alloy vapour.

Preferably, said substrate is a strip.

Preferably, said running substrate is a metallic substrate. Even more preferably, said running substrate is a steel substrate.

Preferentially, said running substrate has a composition comprising, in weight percent: 0.15<Si<0.4; 0.5<Mn<2.5; 0.1<C<0.4; P≤0.03; S≤0.02; 0.01<Al≤0.1; Cu≤0.2; Ti+Nb≤0.20; Cr+Mo≤1 and a balance consisting of Fe and unavoidable impurities.

Preferentially, said running substrate has a composition comprising, in weight percent: 0.15<Si<0.6; 0.17<Mn<2.3; 0.1<C<0.4; P≤0.05; S≤0.01; 0.015≤Al≤1.0; Cu≤0.2; B≤0.005; Ti+Nb≤0.15; Cr+Mo≤1.4 and a balance consisting of Fe and unavoidable impurities.

The vapor jet coater 1 is a sonic vapor jet coater, that is to say a coater capable of generating a vapor jet of sonic velocity. This type of coater is also usually referred to as a JVD (Jet Vapor Deposition) device.

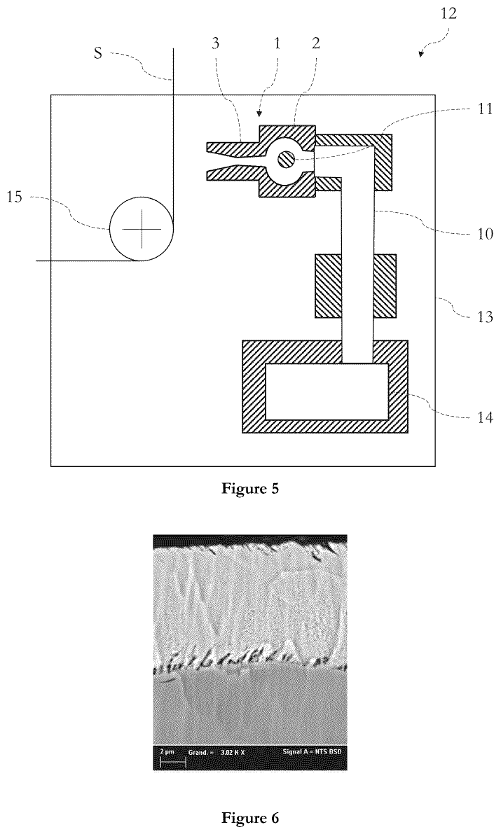

The function of the repartition chamber 2 is to distribute homogeneously the metallic vapour along the vapour outlet orifice and consequently along the substrate width. As illustrated in FIG. 2 and FIG. 5, the repartition chamber 2 is configured to be connectable to an evaporation pipe 10 meaning that a metallic vapour can flow from the evaporation pipe 10 to the repartition chamber 2.

Preferably, the repartition chamber 2 comprises reheating means 11, e.g. a heating cartridge. Such reheating means permit to reheat the metallic vapour coming from the evaporation pipe after its expansion when entering the vapour outlet orifice 3 preventing condensation in the vapour outlet orifice.

Preferably, the reheating means extends along the length of the repartition chamber, even more preferably along the complete length. The number and position of the reheating means can be adjusted to optimize the reheating of the vapour.

The vapour outlet orifice 3 is connected to said repartition chamber 2 meaning that a metallic vapour can flow from the repartition chamber 2 to the vapour outlet orifice 3. This connection is preferably done via an opening cut in the wall of the repartition chamber.

The vapour outlet orifice 3 and the divergent geometry are configured to prevent any flow perturbation in the diverging section.

As illustrated in FIG. 2, the vapour outlet orifice comprises a converging section 4 and a diverging section 7.

The converging section 4 comprises two faces (5, 6), one on each side of the ejection plan (P), which are converging toward each other.

The two faces define an entry side and an exit side. Through the entry side, the metallic vapour enters into the converging section, from the reparation chamber 2. Through the exit side, the metallic vapour exits the converging section.

In a plan perpendicular to the main ejection plan, the faces of the converging section are spaced of a distance C_{ENTRY} on the entry side on of a distance C_{EXIT} on the exit side. Moreover, the ratio

$$\frac{{C}_{ENTRY}}{{C}_{EXIT}}$$

is from 1.2 to 10.

By “converging toward each other”, it is meant that the entry side width of the vapour outlet orifice is smaller than the exit side width. It in no way limits the shape of the sides.

Such a converging section permits to accelerate the jet, i.e. the metallic vapour jet, in order to reach a supersonic speed at the exit of the converging section.

The diverging section 7 comprises two faces (8, 9), one on each side of the ejection plan (P), which are diverging from one another.

The two faces define an entry side and an exit side. Through the entry side, the metallic vapour enters into the diverging section. Through the exit side, the metallic vapour exits the diverging section.

In a plan perpendicular to the main ejection plan, the faces of the diverging section are spaced of a distance D_{ENTRY} on the entry side and of a distance D_{EXIT} on the exit side. Moreover, the ratio

$$\frac{{D}_{E N T R Y}}{{D}_{EXIT}}$$

is from 0.1 to 0.8.

By “diverging from one another”, it is meant that the entry side width of the vapour outlet orifice is lesser than the exit side width. It in no way limits the shape of the sides.

As long as the jet speed is supersonic at the entry side of this section, such a diverging section permits to decelerate the jet, i.e. the metallic vapour jet, and to lower its pressure.

It has been found by the inventors that having such a converging section followed by such a diverging section permits to reduce the jet expansion (for a same vapour flow) when it enters the vacuum chamber due to a decrease of the jet pressure.

The reduction of the jet expansion permits to reduce the porosity of a coating at both steel coating interface and coating top surface.

Preferably, in said converging section, said ratio C_{EE} is from 3 to 5.

Preferably, in said converging section, said two faces are essentially symmetrical to the main ejection plan (P). Such an arrangement improves the homogeneity of the coating.

Preferably, in said converging section, the cross-section along a plan perpendicular to its length is a trapezoid. Even more preferably, in said converging section, the cross-section along a plan perpendicular to its length is an isosceles trapezoid.

Preferably, in said converging section, the base angle of the isosceles trapezoid has a value above 600.

Preferably, the length, L_{CONV}, of the converging section is from 80 mm to 250 mm. The length is along the main ejection direction D.

Preferably, the distance C_{ENTRY} is from 30 mm to 180 mm. Even more preferably, the distance C_{ENTRY} is from 50 mm to 150 mm.

Preferably, the distance C_{EXIT} is from 30 mm to 75 mm. Even more preferably, the distance C_{EXIT} is from 35 mm to 55 mm.

Preferably, an angle between the main ejection plan (P) and any of the two walls defining a converging face (5, 6) is from 5° to 45⁰ and preferentially from 15⁰ to 35⁰.

Preferably, the beginning of the entry of the convergent section 4 presents a radius of curvature Q_{ENTRY} respecting the following condition: 0.5×C_{ENTRY}<Q_{ENTRY}<2×C_{ENTRY}.

Preferably, said diverging section, said ratio D_{EE} is from 0.3 to 0.6.

Preferably, in said diverging section, said two faces are symmetrical to the main ejection plan (P).

Preferably, in said diverging section, the cross-section along a plan perpendicular to its length is a trapezoid. Even more preferably, in said diverging section, the cross-section along a plan perpendicular to its length is an isosceles trapezoid.

Preferably, in said diverging section, the base angle of the isosceles trapezoid has a value above 600.

Preferably, the length of the diverging section is from 30 mm to 280 mm. The length is along the main ejection direction D.

Preferably, the distance D_{ENTRY} is from 20 mm to 60 mm. Even more preferably, the distance D_{ENTRY} is from 30 mm to 50 mm.

Preferably, the distance D_{EXIT} is from 50 mm to 210 mm. Even more preferably, the distance D_{EXIT} is from 60 mm to 200 mm.

Preferably, said converging section and said diverging section are contiguous. Even more preferably, the curvature at the junction between the converging section and the diverging section is below 40⁰ and preferentially below 30⁰.

Preferably, a neutral section comprising a wall comprising two faces, one on each side of said ejection plan (P), is placed between the converging section and the diverging section and said two spaces are spaced from a distance being essentially constant along said main ejection direction D. Even more preferably, the curvature between the converging section and the neutral section is below 40⁰ and preferentially below 30⁰. Even more preferably, the curvature between the diverging section and the neutral section is below 40⁰ and preferentially below 30⁰.

Preferably, as illustrated in FIG. 4, the vapour outlet orifice 3 comprises an end section comprising two parallel faces (80, 90), one on each side of said ejection plan (P), wherein said two faces are spaced from a distance D_{EXIT}. Even more preferably, said end section has a length from 5% to 15% of the length of the diverging section (7).

This end section is downstream the converging section when following the path of the metal vapour.

As illustrated in FIG. 5, the invention also relates to a vacuum deposition facility 12 for continuously depositing, on a running substrate (S), coatings formed from metal or metal alloy, the facility comprising a deposition chamber 13 suited to have the substrate (S) run through along a given path and successively:
an evaporation crucible 14 suited to supply metal or metal alloy vapour,
an evaporation pipe 10,
at least one vapour jet coater 1 as previously described.

The facility comprises means 15 for running the substrate through the deposition chamber. The substrate may be made to run by any suitable means, depending on the nature and the shape of said substrate. A rotary support roller on which a steel strip can bear may in particular be used.

The deposition chamber is preferably a hermetically sealable box which is preferably kept at a pressure from 10⁻⁸ to 10⁻³ bar. Preferably, the deposition chamber has an entry lock and an exit lock between which a substrate S, such as for example a steel strip, can run along a given path in a running direction.

The vapour jet coater is suited to spray onto the running substrate S a metal alloy vapor coming from an evaporation crucible 14.

The evaporation crucible 14 mainly consists of a pot and a cover. The evaporation crucible is provided with heating means enabling the metallic vapor to form and to feed the vapor jet coater. The evaporation crucible is advantageously provided with an induction heater which has the advantage of making the stirring and the composition homogenization of the metal alloy bath easier.

The evaporation pipe 10 is connected on one side to the evaporation crucible 14 and on the other side to the vapor jet coater 1. Preferably, a valve placed between the evaporator and the ejector controls the metallic vapor flow.

These different parts may for example be made of graphite.

The invention also relates to a method for continuously depositing, on a running substrate (S), coatings formed from at least one metal inside a vacuum deposition facility as previously described, wherein the method comprises a step in which, in said vacuum chamber having a pressure P_{VACUUM}, a metallic vapour is ejected through at least one vapour outlet orifice, at a pressure P_{EJECTED}, towards a side of said running substrate and a layer of at least one metal is formed wherein (P_{EJECTED}/P_{VACUUM}) is from 2 to 15 and the ejected vapour has a supersonic speed at said entry side of said diverging section 7.

P_{VACUUM} is the pressure of the chamber which is measured by pressure sensors.

The pressure in the repartition chamber, P_{REP}, can be derived from the zinc mass flowrate, D_{ZINC}, the zinc temperature in the repartition chamber, T_{ZINC}, and the cross section of the ejector throat, A_{THROAT}, using the following formula (1):

$${P}_{REP}^{- 1} = {D}_{ZINC}^{- 1} \times {( \frac{2}{γ + 1} )}^{\frac{γ + 1}{2 ( γ + 1 )}} \times \sqrt{\frac{γ}{R \times {T}_{ZINC}} {A}_{THROAT}} \qquad ( 1 )$$

wherein γ=C_{P}/C_{V}, C_{P} is the specific heat at constant pressure and C_{V} is the specific heat at constant volume and R is the ratio gas constant/molar Mass.

Then, the pressure of the jet ejected by the vapour outlet orifice, P_{EJECTED}, can be calculated using the following formula (2):

$${P}_{EJECTED} = {P}_{R E P} \times {( \frac{\frac{γ + 1}{2}}{1 + \frac{γ - 1}{2} \times {M}^{2}} )}^{\frac{γ}{γ - 1}} \qquad ( 2 )$$

wherein M is the Mach number at the vapour outlet orifice which depends on the D_{EE} ratio and γ=C_{P}/C_{V}, C_{P} is the specific heat at constant pressure and C_{V} is the specific heat at constant volume.

The running substrate is preferably a metallic strip and is even more preferably a steel strip. The width of the running substrate is preferably from 200 to 2200 mm.

The running substrate has preferably a running speed from 10 to 800 m/min.

The layer of said at least one metal is preferably formed by condensation of the ejected vapours.

Preferably, the thickness of the coating is from 0.1 to 20 μm. Below 0.1 μm, the corrosion protection of the coatings would not be sufficient.

The coatings preferably comprise zinc as main element. The coatings may comprise the following additional elements: chromium, nickel, titanium, manganese, magnesium, silicon and aluminium considered individually or in combination.

Preferably, P_{EJECTED}/P_{VACUUM} is from 2 to 10. Such a ratio lowers even further the jet expansion in the vacuum chamber.

Preferably, said P_{VACUUM} is from 1.10⁻⁴ mbar to 3.10⁻¹ mbar.

Preferably, said vapour jet coater is at a distance from 20 mm to 80 mm from the running substrate.

Preferably, the metallic vapour flow ejected by said vapour jet coater is from 3 to 300 g·s⁻¹.

The invention also relates to a steel sheet provided with a metallic coating, produced according as previously described, and optionally including impurities, present in trace amounts, which are unavoidable during production, wherein said metallic coating has a vacancy concentration smaller than 1%.

The steel sheet is preferably hot rolled and then cold rolled to be able to be used for the manufacture of body parts for automobiles. The invention is not necessarily limited to this field and can find a use for any steel component regardless of its end use.

The substrate steel can for example be one particular grades of VHS steel (very high strength, generally between 450 and 900 MPa) or UHR (ultra high strength, generally greater than 900 MPa) the following elements which are rich in oxidizable:
steels without interstitial elements (IF-Interstitial Free), which may contain up to 0.1% by weight of Ti;
dual-phase steels such as steels up to DP 500 DP steels that can contain up to 1200 3% by weight of Mn in combination with up to 1% by weight of Si, Cr and/or Al,
TRIP steels (Plasticity transformation induced) as the TRIP steel 780 which contains for example about 1.6% by weight of Mn and 1.5%% Si;
TRIP steels or Dual-phase containing phosphorus;
TWIP steels (TWining induced plasticity)—steels having a high content of Mn (17-25% by weight generally),
steels such as low density steels that may contain Fe—Al for example up to 10% by weight of Al;
stainless steels, which have a high content of chromes (generally 13-35% by weight), in combination with other alloying elements (Si, Mn, Al . . . )

The vacancy concentration is estimated by comparing the contrast in SEM images. The vacancy was assessed by using around 10 images. The estimation of the vacancy concentration is done on square section, having its sides as big as the coating thickness. The darker pixels correspond to vacancy.

Preferably, said metallic coating comprises at least one layer of pure zinc. The steel sheet may optionally be coated with one or more layers in addition to the zinc layer in a manner suitable to the desired properties of the final product. The zinc layer will preferably be the upper layer of the coating.

Preferably, a layer of paint produced by cataphoresis is on top of said metallic coating.

### EXPERIMENTAL RESULTS

In order to show the influence of the claimed vapour jet coater on the coating compacity, comparative trials have been conducted on steel strips where zinc coatings were formed by means of a jet Vapour Deposition process in the same vacuum deposition facility.

The vacuum deposition facility comprises a deposition chamber suited to have the substrate run through along a given path and successively: an evaporation crucible suited to zinc vapour, an evaporation pipe and one vapour jet coater as illustrated in FIG. 5.

Two samples, A and B, have been produced to compare the results. Both of the coatings were made on a martensitic steel having the same composition, a MS1500 from ArcelorMittal.

In both JVD processes, the pressure in the vacuum chamber, P_{VACUUM}, is of 1.2×10⁻⁴ bar, the distance between the vapour jet coater and the substrate is of 50 mm and the vapour flow is around 108 g·s⁻¹.

The substrate of the sample A has been coated with a vapour jet coater as described in WO 2019/129314, wherein the vapour jet coater comprises only a converging section as illustrated in FIG. 1. The key features of the vapour jet coater are summed up in Table 1.

The substrate of the sample B has been coated with a vapour jet coated as claimed and illustrated in FIG. 4, comprising a converging section, a diverging section and then an end section. The key features of the vapour jet coater are summed up in Table 1.

For each sample, SEM images have been taken and the compacity of the zinc coating has been estimated using 10 SEM images.

The vacancy concentration is strongly reduced when the claimed vapour jet coated is used. Moreover, the zinc coating is more uniform.

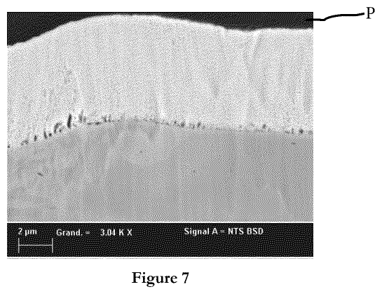

Such an improvement of the coating is also visually noticeable when comparing SEM images of the zinc coatings of samples A (FIG. 6) and B (FIG. 7). The layer of paint is shown partially and schematically as P in black at the top of FIG. 7

From the experiments results, it is clear that the present invention improves the coating by lowering the vacancy concentration.

TABLE 1

| | |
|---|---|
| A (Prior Art) | B (Invention) |

| | |
|---|---|
| Substrate | Martensitic Steel (MS1500) |

Converging section

| | | |
|---|---|---|
| C_{EE} | 2 | 1.4 |
| Length [mm] | 2.4 × 10² | 1.0 × 10² |
| C_{ENTRY} [mm] | 5.0 × 10¹ | 5.0 × 10¹ |
| C_{EXIT} [mm] | 2.5 × 10¹ | 3.5 × 10¹ |

Diverging section

| | |
|---|---|
| D_{EE} | 0.58 |
| Length [mm] | 1.0 × 10² |
| D_{ENTRY} [mm] | 3 × 10¹ |
| D_{EXIT} [mm] | 6 × 10¹ |

End section

| | |
|---|---|
| Length [mm] | 1.0 × 10¹ |

Process parameters

| | |
|---|---|
| P_{VACUUM} [bar] | 1.2 × 10⁻⁴ |

| | | |
|---|---|---|
| P_{EJECTED}/P_{VACCUM} | 57 | 8 |

| | |
|---|---|
| Ejector-Substrate distance [mm] | 50 |

| | | |
|---|---|---|
| Vapour flow [g · s⁻¹] | 110 | 105 |

Products

| | |
|---|---|
| Coating weight | 52 |

| | | |
|---|---|---|
| Vacancy concentration [%] | 3.5 | 0.67 |
| Standard deviation [%] | 1.14 | 0.5 |

What is claimed is:

1-14. (canceled)

15: A vapour jet coater for depositing, on a running substrate, coatings formed from metal or metal alloy, the vapour jet coater comprising successively:
a repartition chamber configured to be connectable to an evaporation pipe, and
a vapour outlet orifice, connected to the repartition chamber and able to eject a metal alloy vapour along a main ejection plane and a main ejection direction, comprising successively:
a converging section including a wall defining first and second converging faces on each side of the main ejection plane, wherein the first and second converging faces are spaced from a distance C_{ENTRY} on an entry side and from a distance C_{EXT} on an exit side, wherein a ratio C_{EE} (C_{ENTRY}/C_{EXT}) is from 1.2 to 10; and
a diverging section including a wall defining first and second diverging faces on each side of the main ejection plane, wherein the first and second diverging faces are spaced from a distance D_{ENTRY} on an entry side and from a distance D_{EXIT} on an exit side, wherein a ratio D_{EE} (D_{ENTRY}/D_{EXIT}) is from 0.1 to 0.8.

16: The vapour jet coater as recited in claim 15 wherein the ratio C_{EE} is from 3 to 5.

17: The vapour jet coater as recited in claim 15 wherein in the converging section, a cross-section along a plane perpendicular to the main ejection direction is a trapezoid.

18: The vapour jet coater as recited in claim 15 wherein the ratio D_{EE} is from 0.25 to 0.35.

19: The vapour jet coater as recited in claim 15 wherein in the diverging section, a cross-section along a plane perpendicular to the main ejection direction is a trapezoid.

20: The vapour jet coater as recited in claim 15 wherein the vapour outlet orifice has an end section including two parallel faces on each side of the main ejection plane, wherein the two parallel faces are spaced by the distance D_{EXIT}.

21: A vacuum deposition facility for continuously depositing, on a running substrate, coatings formed from metal or metal alloy, the facility comprising successively:
an evaporation crucible suited to supply metal or metal alloy vapour;
an evaporation pipe,
a deposition chamber suited to have the substrate run through along a given path and
at least one vapour jet coater as recited in claim 15.

22: A method for continuously depositing, on a running substrate (S), coatings formed from at least one metal inside the vacuum deposition facility as recited in claim 21, the method comprising the step of:
in said vacuum chamber having a pressure P_{VACUUM}, ejecting a metallic vapour through at least one vapour outlet orifice, at a pressure P_{EJECTED}, towards a side of the running substrate and a layer of at least one metal is formed wherein (P_{EJECTED}/P_{VACUUM}) is from 2 to 15 and the ejected vapour has a supersonic speed at the entry side of the diverging section.

23: The method as recited in claim 22 wherein the vapour jet coater is at a distance from 20 mm to 80 mm from the running substrate.

24: The method as recited in claim 22 wherein (P_{EJECTED}/P_{VACUUM}) is from 2 to 10.

25: A method according to any one of the claims 8 to 10, wherein said P_{VACUUM} is from 1.10⁻⁴ mbar and 3.10⁻¹ mbar.

26: The method as recited in claim 22 wherein the metallic vapour flow ejected by said vapour jet coater is from 3 to 300 g·s⁻¹.

27: A steel sheet, produced according to the method as recited in claim 22, provided with the metallic coating and optionally including impurities, present in trace amounts, which are unavoidable during production, wherein the metallic coating has a vacancy concentration smaller than 1 percent.

28: The steel sheet as recited in claim 27 further comprising a layer of paint produced by cataphoresis is on top of said metallic coating.
